(19) United States
(12) Patent Application Publication
(10) Pub. No.: US 2009/0261810 A1
(43) Pub. Date: Oct. 22, 2009

(54) SIMULATOR SYSTEM AND METHOD FOR MEASURING CURRENT VOLTAGE CHARACTERISTIC CURVES OF A SOLAR CONCENTRATOR

(75) Inventors: Steve Askins, Ledyard, CT (US); Sean Taylor, Mountain View, CA (US)

Correspondence Address: THE MUELLER LAW OFFICE, P.C., 12951 Harwick Lane, San Diego, CA, 92130, US

(73) Assignee: SOLFOCUS, INC., Mountain View, CA (US)

(21) Appl. No.: 12/202,377

(22) Filed: Sep. 1, 2008

Related U.S. Application Data
(60) Provisional application No. 61/047,090, filed on Apr. 22, 2008.

(51) Int. Cl. G01R 31/00

(52) U.S. Cl. 324/96

(57) ABSTRACT

A simulator system for simulating operation of a solar panel is disclosed which comprises a solar panel, a reflector positioned across from the solar panel, a light source positioned adjacent to the solar panel for directing light from the light source to the reflector for reflecting light to the solar panel, a sensor positioned adjacent to the solar panel for sensing light reflected from the reflector and for generating a signal indicative of a parameter of the reflected light with the signal having an increasing portion, a flat peak portion, and a decreasing portion, and a circuit for measuring a characteristic of the solar panel when the signal reaches the flat peak portion.

This application claims priority to U.S. Provisional patent application No. 61/047,090 that was filed on Apr. 22, 2008, which is incorporated herein by this reference.

### BACKGROUND OF THE DISCLOSURE

The present disclosure is related to a simulator system for simulating operation of a solar photovoltaic module and more particularly to a simulator system for measuring current-voltage characteristic curves of a solar photovoltaic module.

Solar photovoltaic power is the collection or harvesting of solar energy and converting the energy into electricity that may be used to power various devices. A particular type of device used in a solar system is a solar collector or a solar panel that employs a photovoltaic cell. The photovoltaic cell is used to convert the impinging solar energy into electrical power.

In the development of solar collectors or modules it is important to be able to test the performance of such collectors in an indoor setting. While field testing ultimately needs to be performed on a final design, indoor testing, such as in a laboratory setting or manufacturing environment, can provide more repeatable test conditions, speed development cycles, and be used for factory testing of modules during production. In one aspect of testing solar collectors, and in particular concentrator photovoltaics (CPV), it is important to characterize peak power and acceptance angle. Measuring the peak power requires the ability to measure a current-voltage (I-V) curve. An I-V curve describes the behavior of a solar module in terms of photocurrent produced at different voltage loads. This behavior is dependent primarily on the temperature of the cells and the irradiance (flux of light in Watts per square meter).

Technical requirements for testing CPV modules are more stringent than for flat-plate photovoltaic testers for two reasons. First, CPV panels or modules only accept light that is within a small angle away from the vector normal to the panel. This angle is referred to as the acceptance angle. Therefore, the light source must be highly collimated; that is, parallel to itself. If acceptance angle is to be tested, it is even more important that the angular size of the source (the apparent angle filled by the source as viewed by the module) matches that of the sun as seen from the earth, so that off-axis behavior corresponds to performance in normal operation. Secondly, CPV modules typically use triple-junction solar cells. Triple-junction cell performance is more dependent on spectrum. Specifically, the light that exposes the modules must have the same ratio as sunlight between the energy in two specific bands of spectra: the portion harvested by the top junction and the portion harvested by the middle junction.

Thus, there exists a need for a solar simulator which can accurately test the performance of CPV modules. Other aspects such as improving the efficiency of taking measurements, accommodating various sizes and layouts of modules, and enabling solar simulators to be built in a reliable fashion can further improve the performance and commercialization of solar simulators.

### SUMMARY OF THE DISCLOSURE

In one form of the present disclosure, a system for simulating operation of a solar panel is disclosed which comprises a solar panel, a reflector positioned across from the solar panel, a light source positioned adjacent to the solar panel for directing light from the light source to the reflector for reflecting light to the solar panel, a sensor positioned adjacent to the solar panel for sensing light reflected from the reflector and for generating a signal indicative of a parameter of the reflected light with the signal having an increasing portion, a flat peak portion, and a decreasing portion, and a circuit for measuring a characteristic of the solar panel when the signal reaches the flat peak portion.

In another form of the present disclosure, a system for measuring a characteristic of a semiconductor device comprises a semiconductor device, a control circuit connected to the semiconductor device, an electrical energy storage device connected to the control circuit with the electrical energy storage device for measuring a characteristic of the semiconductor device, and a triggering circuit for receiving a signal having an increasing portion, a flat peak portion, and a decreasing portion and connected to the control circuit with the triggering circuit providing a signal to the control circuit when the received signal reaches the flat peak portion and the control circuit capable of controlling operation of the electrical energy storage device.

In yet another form of the present disclosure, a system for controlling operation of a circuit for measuring a characteristic of an energy conversion device is disclosed with the system comprising an energy conversion device, a reflector positioned away from the energy conversion device, a light source positioned adjacent to the energy conversion device for directing light from the light source to the reflector for reflecting light to the energy conversion device, a sensor circuit positioned adjacent to the energy conversion device for sensing a parameter of light reflected from the reflector and for generating a signal indicative of the parameter of the reflected light with the signal having an increasing portion, a flat peak portion, and a decreasing portion, and a circuit for measuring a characteristic of the energy conversion device, the measuring circuit being connected to the energy conversion device and for receiving the signal from the sensor circuit when the signal reaches the flat peak portion with the signal from the sensor circuit controlling operation of the measuring circuit.

In still another form of the present disclosure, a method of simulating operation of an energy conversion device is disclose with the method comprising the steps of providing a reflector positioned across from an energy conversion device, providing a light source positioned adjacent to an energy conversion device for directing light from the light source to the reflector for reflecting light to an energy conversion device, providing a sensor positioned adjacent to an energy conversion device for sensing light reflected from the reflector and for generating a signal indicative of a parameter of the reflected light with the signal having an increasing portion, a flat peak portion, and a decreasing portion, and providing a circuit for measuring a characteristic of an energy conversion device when the signal reaches the flat peak portion.

Accordingly, a simulator system for measuring current-voltage characteristic curves of a solar concentrator is provided. The present simulator system for measuring current-voltage characteristic curves of a solar concentrator can be easily employed with highly reliable results. The simulator system utilizes one or more optical elements to collimate light from a flash light source, which irradiates one or more concentrator photovoltaic modules to be tested. Also, structures and methods for allowing measurement of current-voltage characteristic curves are described.

These and other advantages of the present disclosure will become apparent after considering the following detailed specification in conjunction with the accompanying drawings.

### BRIEF DESCRIPTION OF THE DRAWINGS

FIG. 1 is a top plan view of a simulator system for simulating operation of a solar concentrator constructed according to the present disclosure;

FIG. 2 is a graph of an irradiance signal;

FIG. 3 is a top plan view of another embodiment of a simulator system for simulating operation of a solar concentrator constructed according to the present disclosure;

FIG. 4 is a partial block diagram and a partial schematic diagram of another embodiment of a simulator system for simulating operation of a solar concentrator constructed according to the present disclosure; and

FIG. 5 is a schematic diagram of a trigger circuit used for controlling operation of a simulator system for simulating operation of a solar concentrator.

### DETAILED DESCRIPTION OF THE EMBODIMENTS

The current disclosure provides collimated light that matches the angular size of the sun. In other words, the focal length is substantially matched to the light source size. By matching the apparent angular size of the light source of the sun, test results obtained by using artificial light, especially for estimates of I-V curves, are more accurate in predicting the performance of that device when used outside in the sunlight. Referring now to the drawings, wherein like numbers refer to like items, number 10 identifies an embodiment of a simulator system for measuring current-voltage characteristic curves of a solar concentrator. The simulator system 10 is shown comprising a solar panel 12, such as a solar concentrator device or CPV, which is mounted to a frame assembly 14. A light source 16 is mounted to a control device assembly 18 that may be mounted to the frame assembly 14. Also mounted in the control device assembly 18 is a light sensor device 20. The light source 16 is capable of producing light such as divergent light, indicated as a light ray or beam 22, which is directed toward a collimator, a collimator optic, or a reflector 24. The reflector 24 is capable of reflecting a light ray or a collimating beam 26 toward the solar panel 12. The collimated beam 26 is used to simulate the light from the sun, which is highly collimated. Once the solar panel 12 is exposed to the collimated beam 26 the solar panel 12 generates electricity with the output (not shown) of the solar panel 12 being connected to the control device assembly 18. Although not shown, the solar panel 12, the light source 16, and the light sensor device 20 may be connected to a circuit or other control device in the control device assembly 18 that includes appropriate hardware and software that is capable of measuring one or more I-V curves associated with the light 26 striking the panel 12. In this manner various I-V curves are generated to determine the power produced by the panel 12. In particular, when the light source 16 is illuminated or pulsed an I-V curve is generated which can correspond to the maximum power that can be generated or produced by the panel 12. In this manner the panel 12 may be tested to determine if the panel 12 meets certain manufacturing requirements or standards.

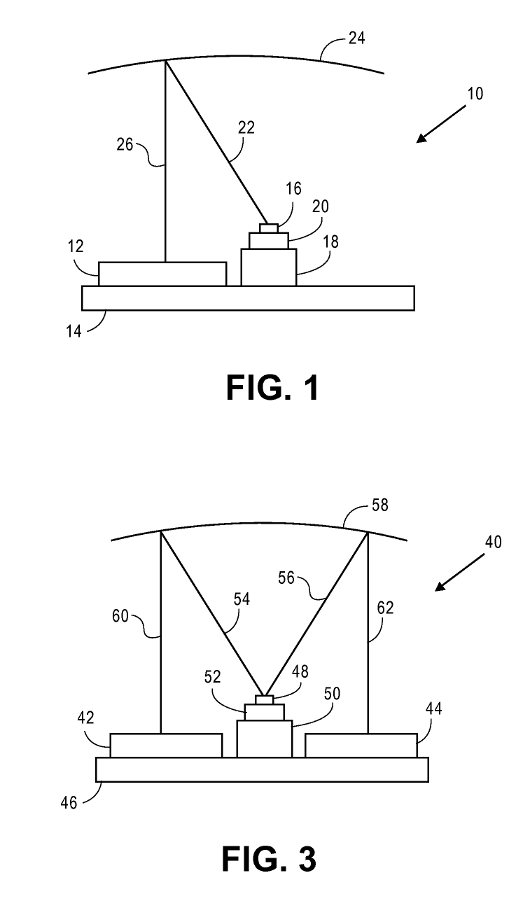

The light source 16 may be a commercial photographic flash strobe or tube, such as a xenon flash strobe that produces a pulse of light. The xenon flash strobe combines high intensity, for a very brief period, with a small overall light source size. With a smaller light source, the required focal distance to achieve the desired collimation is reduced. In addition, the lamp intensity requirement to achieve specific module irradiance is decreased. That is, the closer the light source 16 is to the reflector 24, the brighter the beam of collimated light 26 will be. For example, in FIG. 1 the focal distance for this system 10 is 6.97 meters so that the angular size of a 65 mm diameter flash tube is 0.267°.

The collimator 24 may be a spherical mirror which may be made of slumped, ground, and polished glass. Although a reflective type of collimator has been described, it is also possible and contemplated to use all types of collimators whether they use reflection (e.g. spherical or parabolic reflector), refraction, or diffraction. For instance, other possible embodiments are a reflective lens, a simple lens, a fresnel lens, or an off-axis reflective lens.

The light sensor device 20 may be a reference irradiance detector device which measures the irradiance profile or signal of the light pulse produced by the light source 16. The irradiance profile may be used for the purposes of adjusting the measured photocurrent, triggering a data acquisition circuit, or measuring the spectrum of the light produced by the light source 16. The light sensor 20 should respond to the light from the light source 16 similarly as the solar panel 12 being tested. The device 20 may be a copy of the optics and solar cell assemblies that are tiled together to create the CPV module or the solar panel 12. By using the same cell and optics, configured to the same specifications as the solar panel 12, it is ensured that a valid signal or irradiance profile will be sensed.

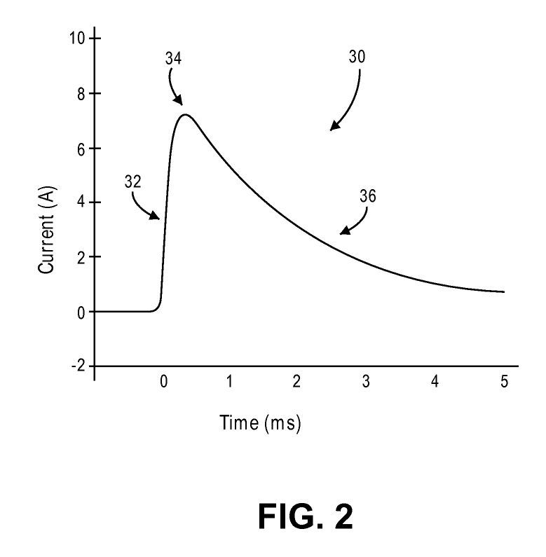

With reference now to FIG. 2, a graph of the irradiance profile or signal 30 is shown. The light sensor 20 is used to detect the irradiance profile 30. The profile 30 has an increasing portion 32, a flat peak portion 34, and a decreasing portion 36. As will be discussed further herein, the irradiance profile 30 is provided to the control device assembly 18 for processing and it is important to be able to detect the flat peak portion 34.

FIG. 3 illustrates a simulator system 40 used for testing I-V curves for a pair of solar panels 42 and 44. The panels 42 and 44 are mounted to a frame assembly 46. A light source 48 is mounted to a control device assembly 50 that may be mounted to the frame assembly 46. Also mounted in the control device assembly 50 is a light sensor device 52. The light source 48 is capable of producing light such as divergent light, indicated as a light rays or beams 54 and 56, which are directed toward a collimator, a collimator optic, or a reflector 58. The reflector 58 is capable of reflecting a light ray or a collimating beam 60 toward the solar panel 42 and a light ray or a collimating beam 62 toward the solar panel 44. Although not shown, the outputs of the solar panels 42 and 44 are connected to the control device assembly 50. In order to test the power generated by both of the solar panels 42 and 44, the light source 48 is operated, the light sensor device 52 detects the light pulse generated by the light source 48, and the control device assembly 50 monitors the outputs of the solar panels 42 and 44. In this manner, the two solar panels 42 and 44 may have their I-V curves measured simultaneously. Being able to test two panels at the same time decreases the testing time. Further, it is possible and contemplated to have the solar panels 42 and 44 mounted on a conveyor system which may be positioned in the system 40 to measure the I-V curves of each of the panels 42 and 44. Other solar panels may be mounted to the conveyor system for testing or measuring the I-V curves of each of the panels in an assembly line like manner.

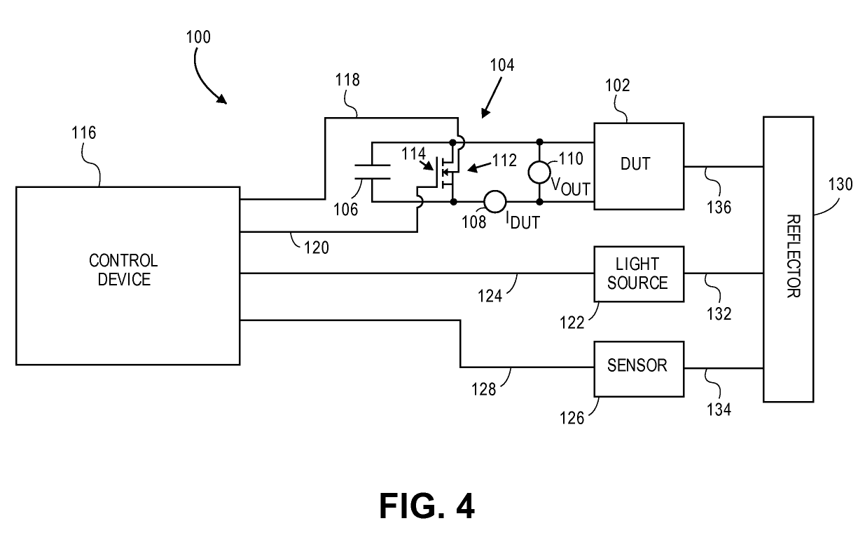

Referring now to FIG. 4, a block diagram of a simulator system 100 for measuring I-V characteristic curves of a solar concentrator is illustrated. The simulator system 100 comprises a device under test (DUT) 102, such as a solar panel or CPV, which is connected to a measuring circuit 104. The measuring circuit 104 comprises a capacitor 106, a current transducer 108, a voltage transducer 110, and a drive or logic circuit 112. The drive circuit 112 may be a field effect transistor (FET) 114 that is connected to a control device 116 via leads 118 and 120. The DUT 102 is directly connected to the capacitor 106 and the transistor 114 is used to controllably short out the capacitor 106. When a control signal is sent to the drive circuit 112 over the leads 118 and 120, the transistor 114 is turned off very quickly. This causes the transistor 114 to act like an open circuit.

The simulator system 100 also comprises a light source 122 positioned adjacent to the DUT 102 with the light source 122 being electrically connected to the control device 116 by a wire 124 and a reference power unit or sensor device 126 which is also connected to the control device 116 by a wire 128. The control device 116 may include various components such as a microprocessor, a microcontroller or other similar control circuit, or a computer system having various storage devices, input devices, and output devices. A reflector 130 is positioned across from the DUT 102, the light source 122, and the sensor 126. The light source 122 may be placed at the focus of the reflector 130. Although not shown, it is also possible to test another solar panel in this particular arrangement. Various housings or assemblies for holding or positioning the DUT 102, control device 116, the light source 126, the sensor 126 and the reflector 130 have not been shown in this particular drawing.

To measure the I-V characteristic curves of the DUT 102 the light source 122 is energized to produce a single flash of light 132 to be directed to the reflector 130. The light source 122 is operated under the control of the control device 116 by sending a signal over the wire 124. The reflector 130 reflects a collimated beam 134 to the sensor 126 and a collimated beam 136 to the DUT 102. The sensor 126 sends a signal indicative of the collimated beam 134 over the connection 128 to the control device 116. An example of the signal sent is shown in FIG. 2 as the signal 30. Once the signal is sent to the control device 116, the control device 116 processes the signal and at a predetermined time, as will be explained more fully herein, sends a trigger signal to the drive circuit 112 to turn off the transistor 114. At this point, the current transducer 108 measures the current generated by the DUT 102 and the voltage produced by the DUT 102 is measured by the voltage transducer 110. The measured current and voltage are provided to the control device 116 for generating an I-V curve. The control device 116 may include software for controlling operation of the system 100 and for implementing the various steps or process just described. Additionally, the software may be used to determine if the I-V curve is within standards for the DUT 102 or whether the DUT 102 is defective.

The system 100 continuously and passively varies the load voltage without having to dissipate the power generated by the DUT 102. Since the system 100 is passive, the system 100 does not have to accurately and actively drive the DUT 102 to a specific voltage and current is not forced back into the DUT 102. In addition, the circuit 104 allows for the I-V curve to be taken or measured very quickly. The system 100 uses a high-speed sweep and uninterrupted current such that there are no high-speed transitions to cause problems with the inductance of the DUT 102. The voltage transducer 110 and current transducer 108 are designed for high-speed, high-power measurement such that there is little error due to wide frequency content. It is also possible to use a linear amplifier to make an active sweep at a desired speed instead of passively sweeping the voltage.

The sensor 126 may be one or more reference irradiance detectors that may be used to measure the irradiance profile during the pulse of light. This measurement may be used for the purposes of adjusting the measured photocurrent, triggering a data acquisition circuit, or measuring the spectrum. In the system 100 that is used to test a CPV, the reference detector or sensor 126 must respond to light input similarly to the DUT 102 being tested. Otherwise, it is not a valid signal to use for normalization or for triggering. The reference power unit or sensor 126 is defined as a copy of the optics and solar cell assemblies that are tiled together to create a CPV module such as the DUT 102. Furthermore, the spectral response of the reference power unit 126 will be similar to the DUT 102. Since the same solar cell and optical components are used in the sensor 126 as in the DUT 102, the spectrum of light exposing the cell, which for the DUT 102 is the light transmitted through the optics rather than the light exposing the front of the DUT 102 will be the same. Lastly, the concentration of the light falling on the sensor 126 will be similar to that falling on the cells of the DUT 102. Because the cells operate differently at different concentrations of light, this further ensures a similar response between the sensor 126 and the DUT 102.

Because each junction of the multi-junction cells which are often used for CPV modules typically responds to a separate, specific band of the spectrum, and because such junctions are electrically connected in a series circuit, it is important that the light used to expose such CPV modules has spectral characteristics similar to the sun. The spectrum need not exactly match the sun's, but the flux of the simulated light integrated across the bands to which each junction responds must have the correct ratio with that of the other junctions. The correct ratio is defined by the ratios extent in the solar light at the time of day, time of year, and geographic location that the test is intended to simulate. Furthermore, for CPV modules, the spectral transmission characteristic of the optics must be taken into account.

The system 100 is used for exposing the DUT 102 with collimated light of appropriate spectrum, measuring that light with one or more reference power units or sensors 126, and measuring the I-V characteristics of the DUT 102 during a short flash. The system 100 may be utilized with software to adjust these current and voltage measurements for time-varying irradiance and panel inductance, as well as temperature, and light properties such as spectrum and collimation. This will enable the calculation of a power estimate for a set of standard temperature and irradiance.

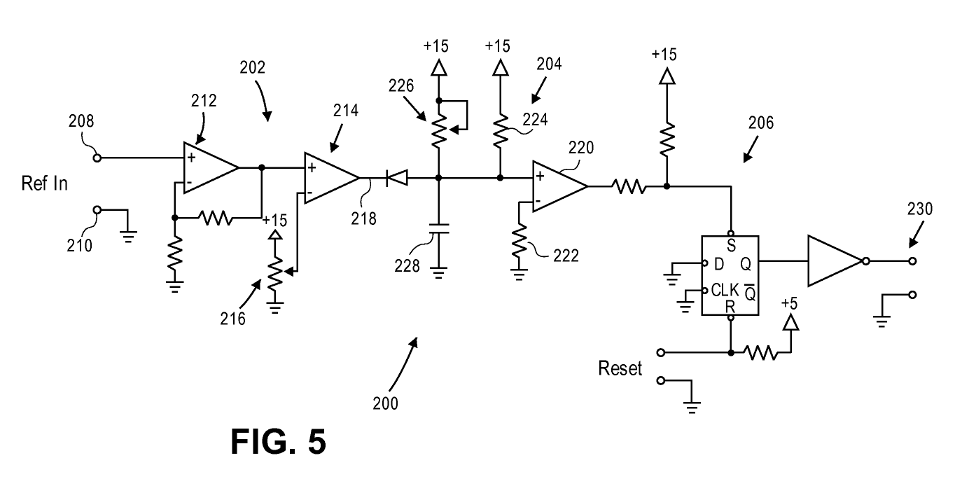

FIG. 5 illustrates a schematic diagram of a trigger circuit 200 used for controlling the operation of the drive circuit 112 shown in FIG. 4. The trigger circuit 200 comprises a level/threshold circuit 202, a time delay circuit 204, and a latch circuit 206. The trigger circuit 200 is connected a light sensor, such as the sensor 126 shown in FIG. 4, at input terminals 208 and 210. The signal provided from the light sensor 126, with an example of the signal being the signal 30 shown in FIG. 2, is provided to the level/threshold circuit 202. The purpose of the trigger circuit 200 is to control the operation of the drive circuit 112 (FIG. 4) to take an I-V measurement when the signal 30 reaches the flat peak portion 34. The level/threshold circuit 202 includes a buffer 212 and a comparator 214 with an adjustable level resistor 216. The level/threshold circuit 202 provides a signal to the time delay circuit 204 from an output 218 of the comparator 214. The time delay circuit 204 includes an operational amplifier 220, a pair of resistors 222 and 224, an adjustable resistor 226, and a capacitor 228. The time delay circuit 204 is adjusted by use of the adjustable resistor 226 so that an output 230 of the trigger circuit 200 occurs when the signal 30 reaches the flat peak portion 34. The latch circuit 206 prevents the output 230 from exhibiting any noise and maintains the state after the irradiance level or signal 30 in FIG. 2 has dropped, which is shown as the decreasing portion 34 in FIG. 2. By using the level/threshold circuit 202, the time delay circuit 204, and the latch circuit 206 noise problems related to switching are alleviated and consistent timing can be achieved. The output 230 of the trigger circuit 200 is provided to the drive circuit 112.

Because the timing of the I-V measurement with respect to the irradiance of the flash from the light source is critical, the trigger circuit 200 allows for continuously monitoring the irradiance signal and for triggering an external event at a specific time. The trigger circuit 200 reduces the amount of extraneous data. The timing of data acquisition, the I-V characteristic curves, to the flash pulse is automatically determined and is repeatable.

While the specification has been described in detail with respect to specific embodiments, it will be appreciated that those skilled in the art, upon attaining an understanding of the foregoing, may readily conceive of alterations to, variations of, and equivalents to these embodiments. These and other modifications and variations to the present system for simulating operation of a solar panel may be practiced by those of ordinary skill in the art, without departing from the spirit and scope of the present subject matter, which is more particularly set forth in the appended claims. Furthermore, those of ordinary skill in the art will appreciate that the foregoing description is by way of example only, and is not intended to be limiting. Thus, it is intended that the present subject matter covers such modifications and variations as come within the scope of the appended claims and their equivalents.

What is claimed is:

1. A simulator system for simulating operation of a solar panel, the simulator system comprising:
a solar panel;
a reflector positioned across from the solar panel;
a light source positioned adjacent to the solar panel for directing light from the light source to the reflector for reflecting light to the solar panel;
a sensor positioned adjacent to the solar panel for sensing light reflected from the reflector and for generating a signal indicative of a parameter of the reflected light with the signal having an increasing portion, a flat peak portion, and a decreasing portion; and
a circuit for measuring a characteristic of the solar panel when the signal reaches the flat peak portion.

2. The simulator system of claim 1 wherein the measuring circuit comprises a control circuit connected to the solar panel and a electrical energy storage device connected to the control circuit with the control circuit capable of controlling operation of the electrical energy storage device.

3. The simulator system of claim 2 wherein the measuring circuit further comprises a voltage sensor device and a current sensor device.

4. The simulator system of claim 2 wherein the control circuit comprises a trigger circuit with the trigger circuit capable of generating a signal based upon when the signal generated by the sensor reaches the flat peak portion.

5. The simulator system of claim 4 wherein the trigger circuit is connected to the sensor.

6. The simulator system of claim 4 wherein the trigger circuit comprises a level threshold circuit for receiving the signal indicative of a parameter of the reflected light, a delay circuit connected to the level threshold circuit, and a latch circuit having an output.

7. The simulator system of claim 6 wherein the output of the latch circuit is connected to the control circuit of the measuring circuit.

8. A system for measuring a characteristic of a semiconductor device comprising:
a semiconductor device;
a control circuit connected to the semiconductor device;
an electrical energy electrical energy storage device connected to the control circuit with the electrical energy storage device for measuring a characteristic of the semiconductor device; and
a triggering circuit for receiving a signal having an increasing portion, a flat peak portion, and a decreasing portion and connected to the control circuit with the triggering circuit providing a signal to the control circuit when the received signal reaches the flat peak portion and the control circuit capable of controlling operation of the electrical energy storage device.

9. The system of claim 8 wherein the control circuit comprises a transistor for switching the electrical energy storage device on or off.

10. The system of claim 8 wherein the triggering circuit comprises a level threshold circuit, a delay circuit connected to the level threshold circuit, and a latch circuit having an output.

11. The system of claim 10 wherein the output of the latch circuit is connected to the control circuit.

12. The system of claim 10 wherein the triggering circuit further comprises a light sensor that generates the received signal to the triggering circuit.

13. A system for controlling operation of a circuit for measuring a characteristic of an energy conversion device, the system comprising:
an energy conversion device;
a reflector positioned away from the energy conversion device;
a light source positioned adjacent to the energy conversion device for directing light from the light source to the reflector for reflecting light to the energy conversion device;
a sensor circuit positioned adjacent to the energy conversion device for sensing a parameter of light reflected from the reflector and for generating a signal indicative of the parameter of the reflected light with the signal having an increasing portion, a flat peak portion, and a decreasing portion; and
a circuit for measuring a characteristic of the energy conversion device, the measuring circuit being connected to the energy conversion device and for receiving the signal from the sensor circuit when the signal reaches the flat peak portion with the signal from the sensor circuit controlling operation of the measuring circuit.

14. The system of claim 13 wherein the light source is a flash generator.

15. The system of claim 13 wherein the sensor circuit is capable of measuring irradiance of light reflected from the reflector.

16. The system of claim 13 wherein the measuring circuit comprises a control circuit connected to the energy conversion device and a electrical energy storage device connected to the control circuit with the control circuit capable of controlling operation of the electrical energy storage device.

17. The system of claim 16 wherein the control circuit comprises a transistor for switching the electrical energy storage device on or off.

18. The system of claim 13 wherein the sensor circuit comprises a trigger circuit with the trigger circuit capable of generating a signal based upon when the signal generated by the sensor circuit reaches the flat peak portion.

19. The system of claim 18 wherein the trigger circuit comprises a level threshold circuit, a delay circuit connected to the level threshold circuit, and a latch circuit having an output.

20. The system of claim 13 wherein the measuring circuit further comprises a voltage sensor device and a current sensor device.

21. A method of simulating operation of an energy conversion device, the method comprising the steps of:
providing a reflector positioned across from an energy conversion device;
providing a light source positioned adjacent to an energy conversion device for directing light from the light source to the reflector for reflecting light to an energy conversion device;
providing a sensor positioned adjacent to an energy conversion device for sensing light reflected from the reflector and for generating a signal indicative of a parameter of the reflected light with the signal having an increasing portion, a flat peak portion, and a decreasing portion; and
providing a circuit for measuring a characteristic of an energy conversion device when the signal reaches the flat peak portion.

22. The method of claim 21 further comprising the step of providing a control circuit connected to the solar panel and an electrical energy storage device connected to the control circuit with the control circuit capable of controlling operation of the electrical energy storage device.

23. The method of claim 22 further comprising the step of providing a trigger circuit with the trigger circuit capable of generating a signal based upon when the signal generated by the sensor reaches the flat peak portion.

24. The method of claim 23 further comprising the step of providing a level threshold circuit for receiving the signal indicative of a parameter of the reflected light, a delay circuit connected to the level threshold circuit, and a latch circuit having an output.
